(19) United States
(12) Patent Application Publication
(10) Pub. No.: US 2012/0097526 A1
(43) Pub. Date: Apr. 26, 2012

(54) ROTARY MAGNETRON

(76) Inventors: John E. Madocks, Tucson, AZ (US); Jeffrey F. Vogler, Tucson, AZ (US)

(21) Appl. No.: 13/262,724

(22) PCT Filed: Apr. 5, 2010
(86) PCT No.: PCT/US2010/029956

§ 371 Date: Nov. 22, 2011

Related U.S. Application Data
(60) Provisional application No. 61/211,838, filed on Apr. 3, 2009.

(51) Int. Cl. C23C 14/35; C23F 4/04

(52) U.S. Cl. 204/192.12; 204/298.16; 204/298.09; 204/298.37; 204/192.32

(57) ABSTRACT

A rotary magnetron is provided with an end block for rotatably supporting a target on an axis of rotation. An elongate magnetic bar assembly is disposed within the target. A stator shaft is affixed in the end block; one end of the stator shaft is coupled to the elongate magnetic bar assembly to support the elongate magnetic bar assembly. The target has a target shaft extending over the stator shaft and rotatable thereon around the axis of rotation. The rotary magnetron is characterized by a rotating coolant seal disposed inside the target shaft proximate the one end of the stator shaft and proximate to the elongate magnetic bar assembly.

### CROSS-REFERENCE TO RELATED APPLICATION

This application claims priority of U.S. Provisional Patent Application Ser. No. 61/211,838 filed Apr. 3, 2009, which is incorporated herein by reference.

### FIELD OF THE INVENTION

The present invention pertains in general to rotary magnetrons, and in particular to a rotary magnetron with a more durable coolant seal.

### BACKGROUND OF THE INVENTION

Rotary magnetrons are well known in the art, beginning with McKelvey's original invention of the device. Since its invention and particularly since the expiration of the original patent, there have been several advances improving aspects of the device.

Rotary magnetrons assemblies are used as a cathode to sputter material from a target to a substrate. A rotary magnetron cathode target assembly typically comprises a stationary magnet, a rotatable target, a shaft for connecting to a drive mechanism for rotating the target, coolant connections, and electrical connections. The magnet is a bar assembly located inside the target tube and remains stationary as the target tube is rotated around it. The target tube is coupled to a rotatable shaft that is rotated by a drive mechanism that rotates the shaft and target. End blocks are used at either end of the target to support the shaft and target, rotate, energize, cool, and provide sealing of the target. A single end block at one end is often used to support a cantilevered target tube to facilitate installation.

In prior rotating magnetron assemblies, a water seal was located inside an end block at the end of the stator shaft away from the magnet bar. In other prior magnetron assemblies the water seal is mounted in radial alignment to the bearing or vacuum seal.

In prior rotating magnetron assemblies, with the rotating water seal positioned distal from the magnet bar, the stator shaft was relatively thin and small in diameter. This was a result of the limitations of the water seal dimensions and the size of the vacuum seal and support bearings. To adequately support the magnet bar in such prior assemblies an additional “water” bearing was added between the target shaft and stator shaft. When the water bearing wears, the magnet bar becomes less rigidly supported. This wear of the water bearing causes the magnet bar to sag down and progressively be farther from correct parallel alignment with the target tube. This is especially for long target tubes that have the weight of magnet bars cantilevered further from the water bearing.

### SUMMARY OF THE INVENTION

An inventive rotary magnetron has a water seal disposed at the end of the stator shaft proximate the magnetic bar and preferably the water seal is a rotating water seal. With the water seal so disposed, the size of the stator shaft can be made large and better able to support the weight of the target tube. The result is that the stator shaft can support the target tube and the static magnet bar inside the rotating target tube without need for a water bearing. A rotary magnetron independent of a water bearing has economic and operational benefits.

In the embodiment, the end block of a rotary magnetron is of a simpler construction and with fewer parts than prior art rotary magnetrons, so as to reduce magnetron maintenance and improve reliability.

A rotary magnetron is provided with an end block for rotatably supporting a target on an axis of rotation. An elongate magnetic bar assembly is disposed within the target. A stator shaft is affixed in the end block; one end of the stator shaft is coupled to the elongate magnetic bar assembly to support the elongate magnetic bar assembly. The target has a target shaft extending over the stator shaft and rotatable thereon around the axis of rotation. The rotary magnetron is characterized by a rotating coolant seal disposed inside the target shaft proximate the one end of the stator shaft and proximate to the elongate magnetic bar assembly. The rotating coolant seal has sealing surfaces either parallel to, or perpendicular to, the axis of rotation. A water bearing is no longer required and the rotary magnetron is provided independent of such a water bearing (without being present). A greater coolant flow volume is provided through a high ratio of transverse (relative to axis of rotation) area of coolant inlet passages relative to stator area of 0.06:1 or greater.

### BRIEF DESCRIPTION OF THE DRAWINGS

The invention will be better understood from a reading of the following detailed description of an embodiment of the invention in conjunction with the drawing figures in which like reference designators are used to identify like elements, and in which:

FIG. 1 is a perspective view of an inventive rotary magnetron mounted on a chamber lid;

FIG. 2 is a cross-section view of the rotary magnetron of FIG. 1 taken through a longitudinal vertical plane along lines 2-2;

FIG. 3 is a magnified cross-section view of a portion of one end block of FIG. 2;

FIG. 4 shows a partial end view of the stator support shown in FIGS. 2 and 3 taken in the direction of line 4-4 in FIG. 1; and

FIG. 5 is a magnified cross-section view of a portion of one end block showing a lip seal embodiment of an inventive rotary magnetron with a rotary seal surface parallel to the axis of rotation.

### DETAILED DESCRIPTION OF THE PREFERRED EMBODIMENTS

The present invention has utility as a rotary magnetron for etching or depositing thin films on substrates. An inventive rotary magnetron has a water seal disposed at the end of the stator shaft proximate the magnetic bar and preferably the water seal is a rotating water seal. With the water seal so disposed, the size of the stator shaft can be made large and better able to support the weight of the target tube. The result is that the stator shaft can support the target tube and the static magnet bar inside the rotating target tube without need for a water bearing. A rotary magnetron independent of a water bearing has economic and operational benefits.

In the embodiment, the end block of a rotary magnetron is of a simpler construction and with fewer parts than prior art rotary magnetrons, so as to reduce magnetron maintenance and improve reliability.

Turning now to the figures, a rotary magnetron is shown generally at 100 and mounted on a lid 104. Lid 104 fits on a vacuum chamber as part of a plasma sputtering apparatus, which is not shown. Lid 104 and vacuum chamber details for rotary magnetrons are known to the art.

The rotary magnetron 100 includes a rotating target tube 101 and end blocks 102, 103. End block 102 is a drive end block and includes water and vacuum connections. End block 103 is an electrical commutation end block. It will be appreciated by those skilled in the art that in other embodiments the electrical connections may be included in end block 102.

Proximate end block 102, a drive motor 106 is mounted on the atmosphere side of lid 104. Timing belt 108 extends form the atmosphere side of lid 104 to the vacuum side of lid 104. Water supply and return lines 107 are provided proximate end block 102.

High voltage connection points 105 protrude from the atmosphere side of lid 104 proximate end block 103.

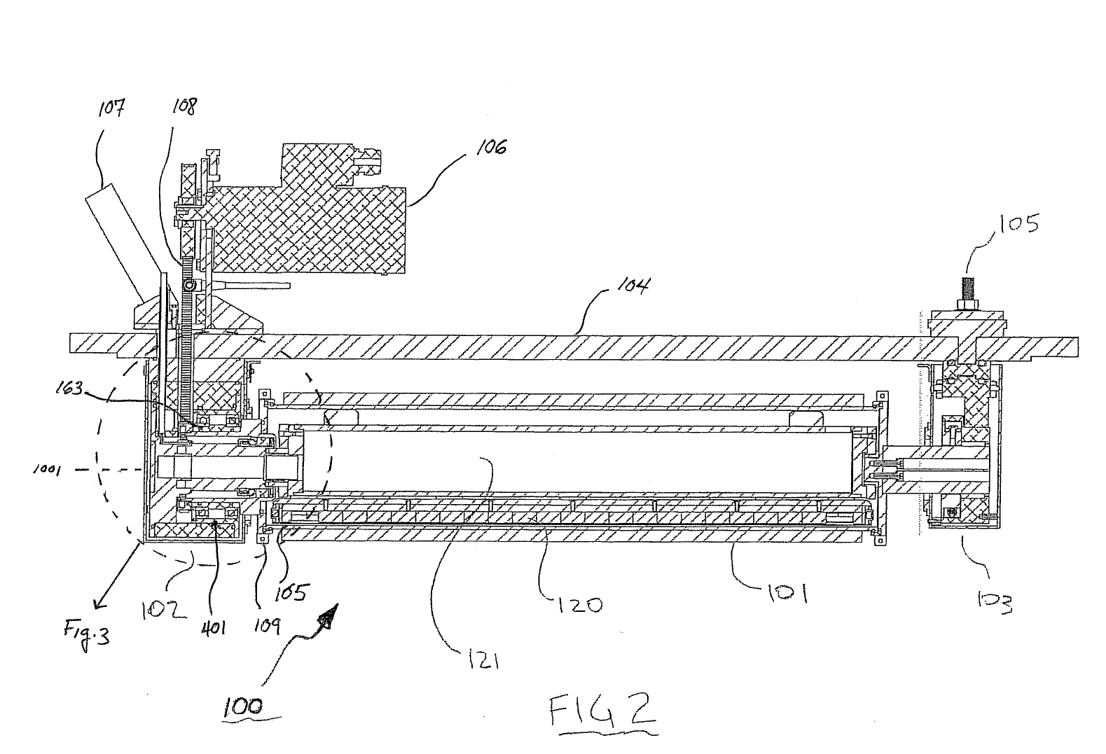

As particularly well shown in FIG. 2, a magnet pack or bar 120 is disposed within target tube 101. Magnet pack 120 is attached to magnet bar assembly 121. The internal components of both end blocks 102 and 103 are also easily seen in FIG. 2.

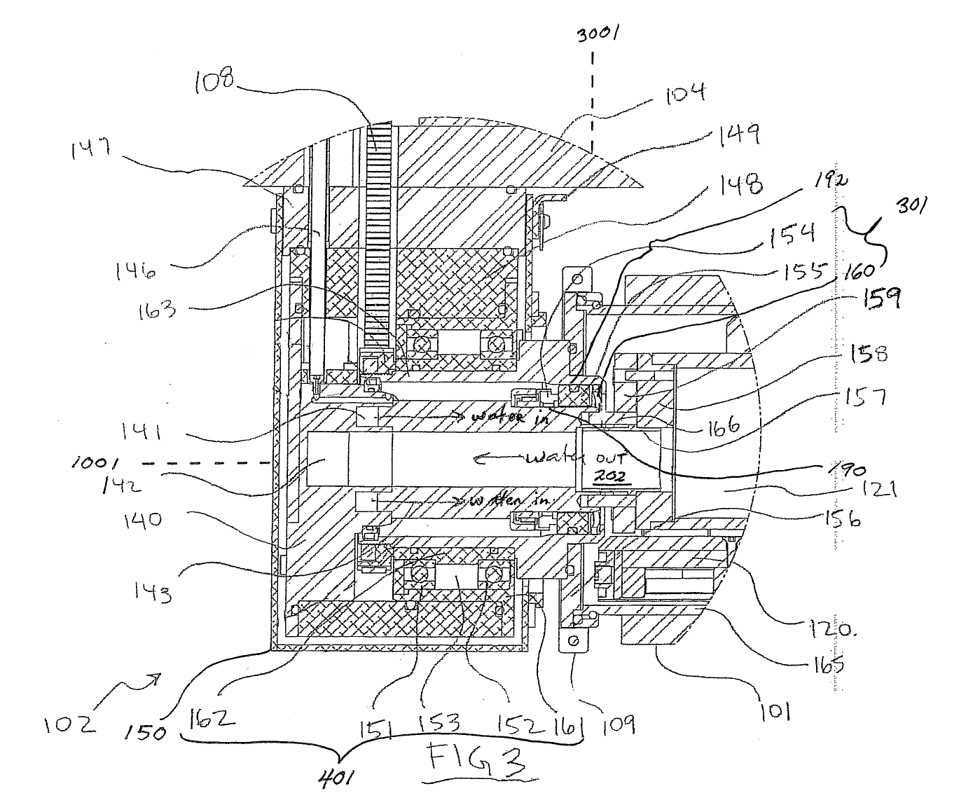

FIG. 3 more clearly details the end block 102. End block 102 provides coolant supply to, and return from target tube 101, rotation of target tube 101, bearing support of target tube 101, support of the non-rotating magnet bar 121 and an air to vacuum seal.

End block 102 is mounted to lid 104 via fasteners 115. It will be appreciated by those skilled in the art that various other fastening arrangements may be utilized to affix end block 102 to lid 104. End block 102 is at target voltage in operation of rotary magnetron 100 and lid 104 is at electrical ground.

To electrically isolate end block 102 from the grounded chamber lid 104, a nonconducting polymer or ceramic block 147 is sandwiched between end block core 148 and lid 104.

End block 102 includes an external end block sheet metal cover assembly 150. Cover assembly 150 is electrically floating and is held away from the high voltage end block 102 by alumina insulators, not all of which are shown, and a pin through insulator block 147.

An electrically floating sheet metal angle shield 149 helps keep sputtered flux from reaching the insulator block 147.

Target tube 101 is assembled with a backing tube 165 and clamped to a rotating target shaft 163 via clamp set 109. Target shaft 163 is supported by a bearing/seal assembly 401 that includes bearings 151 and 152 and bearing inner and outer members 162 and 161 respectively. Bearing/seal assembly 401 also includes an integrated vacuum seal 153 that optionally uses a ferromagnetic sealing fluid. Bearing/seal assemblies, such as assembly 401, are commonly called “Ferro fluid couplings” and are commercially available from a number of vendors. Bearing/seal assembly 401 supports target shaft 163 and target tube 101.

Target shaft 163 carries a pulley 114 that is turned by belt 108 that is in turn coupled to drive motor 106. It will be apparent to those skilled in the art that other drive mechanisms may be utilized to rotate target shaft 163. Target shaft 163 is rotated along an axis 1001 that extends through target 101.

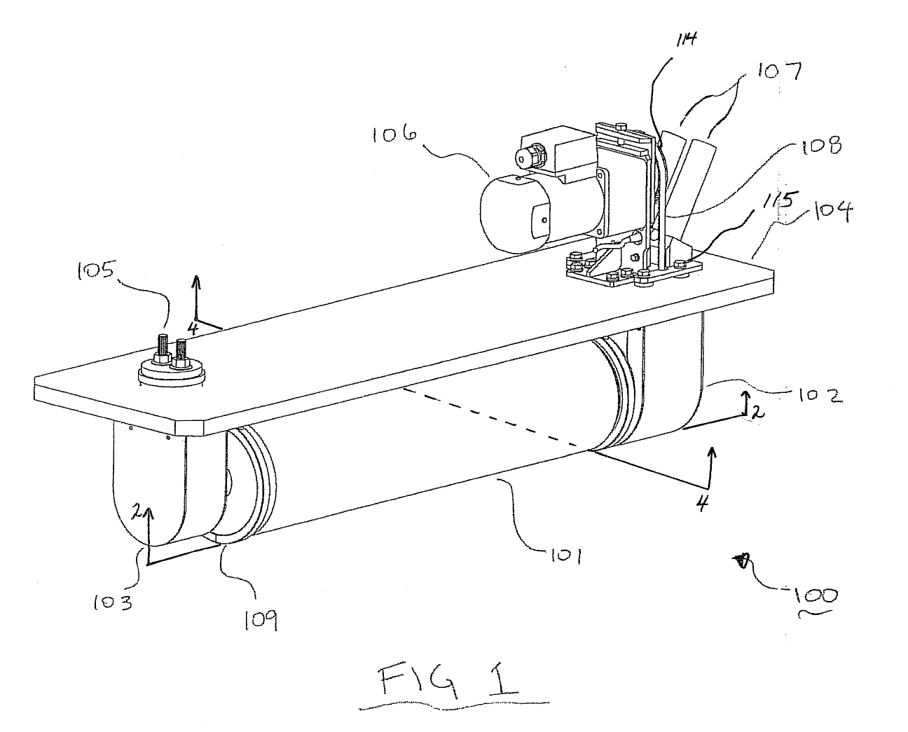

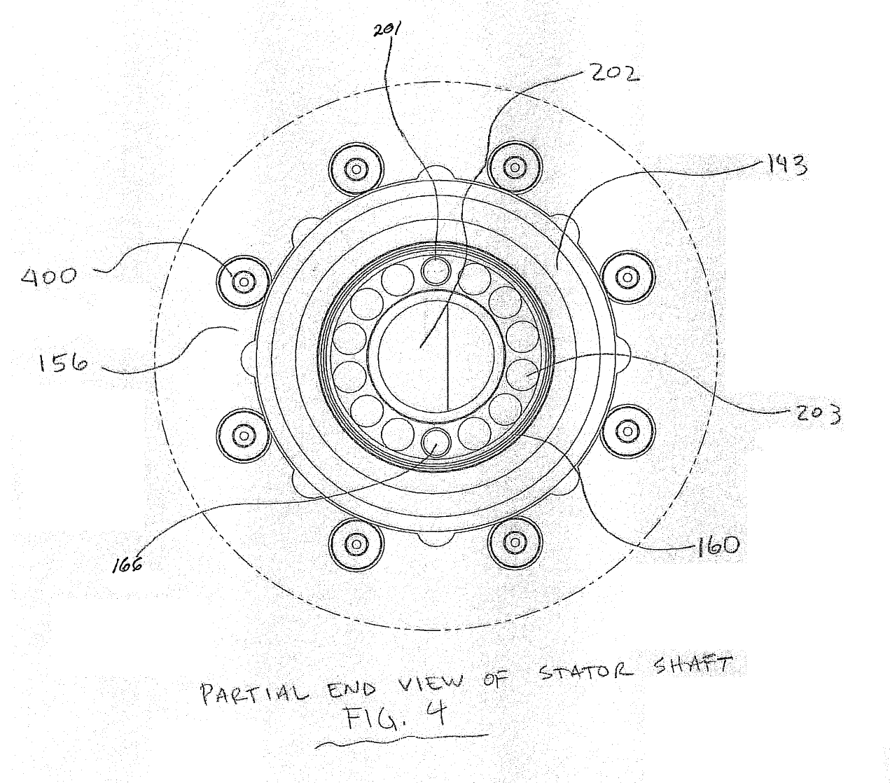

Target cooling fluid flows between an external source through connections 107 shown in FIG. 1 to a water housing 140 disposed within end block 102. Cooling fluid, which in the illustrative embodiment is water, flows into target tube 101 from cavity 141 in water housing 140 through passages 203 in stator shaft 143 which extend parallel to axis 1001. Ends of flow passages 203 are seen in the end view of the stator shaft 143 in FIG. 4. The cooling fluid exits passages 203 into target tube 101. After the cooling fluid flows the length of the target tube 101, the cooling fluid flows back through the inside of magnet bar assembly 121 and then into a central flow passage 202 through the center of the stator shaft to a cavity 142 in water housing 140. Magnet bar 121 components 157, 159 and 158 provide fluid communication to conduct return coolant from the magnet bar 121 into passage 202 of stator shaft 143. Pins 166 extending from magnetic bar 121 are received in bore holes 201 of stator shaft 143 to prevent magnet bar 121 from rotating inside the target tube 101. Stator tube 143 is affixed to water housing 140. Affixation is illustratively provided by welding. A target flange 156 is retained around stator tube 143 by flange fasteners 400.

An inventive rotary magnetron with a water seal 301 positioned proximal to the stator shaft 143 provides a larger area for coolant flow than in conventional rotary magnetrons, thereby affording greater cooling efficiency. While a conventional rotary magnetron has a transverse cross-sectional area ratio between water inlet tubing in the end block at the stator tube relative to the stator tube area of less than 0.04:1, the present invention through positioning of the water seal 301 proximal to the stator shaft 143 optionally provides coolant inlet to stator tube transverse cross-sectional area ratios equal to or greater than 0.06:1, 0.10:1, and even greater than 0.12:1. As shown in FIG. 4, twelve water inlets 203 arrayed around the stator tube 143 define an area ratio of 0.12:1. By more efficiently cooling a rotary magnetron, higher throughput of substrate modification is achieved in a given time period only through water seal placement according to the present invention.

It is important in rotating magnetrons that magnet pack 120 be held not only from rotating but also parallel to rotating target tube 101. If the magnet pack 120 is not maintained parallel to target tube 101, sputtering uniformity on a substrate such as glass suffers. It is the job of the stator shaft 143 to support the magnet bar 121 rigidly in alignment with the rotating target tube 101.

A coolant seal 301 is provided so that the coolant fluid flows from stator tube 143 into rotating target tube 101 without leakage. Preferably, coolant seal 301 is rotating and providing a non-rotatable sealing surface 190 carried on stator tube 143 and a rotatable sealing surface 192 carried on target shaft 163. The non-rotatable surface is provided by a ring 154 carried on stator tube 143. The ring 154 is readily formed of graphite, turbostratic carbon, fullerenes, or other sp² hybridized carbon atom containing inorganic carbon containing substance. Alternatively an O-ring is provided that statically seals ceramic ring 155 along with a retainer ring to hold ring 154 in place and thereby statically seal ring 154 against stator shaft 143. The rotatable surface 192 is provided by a rotating ceramic ring 155 carried by target shaft 163. A wave washer 160 provides a force against rotating ceramic ring 155 to urge the surfaces of rings 154, 155 against each other to provide the fluid barrier water seal 301. A ceramic ring 155 is illustratively formed of alumina, titania, SiN, mullite, and combinations thereof.

As shown in FIG. 3, the coolant seal 301 is located proximate to or at the end of the stator shaft 143 and proximate or just prior to the magnet bar 121. The sealing surfaces are disposed in a plane 3001 that is perpendicular to axis 1001 and spaced longitudinally along axis 1001 from bearing/seal assembly 401.

No water flows in the gap between the target shaft 163 and stator shaft 143. If coolant seal 301 ever were to leak, this normally dry void will fill up with the coolant fluid. A seal 144 prevents this leaking water from moving inside end block 102. A leak hole 145 and tube 146 provide a path for water should water seal 301 leak. It is important to keep end block 102 free of water because ferrofluid couplings are damaged when liquid water comes in contact with the ferrofluid.

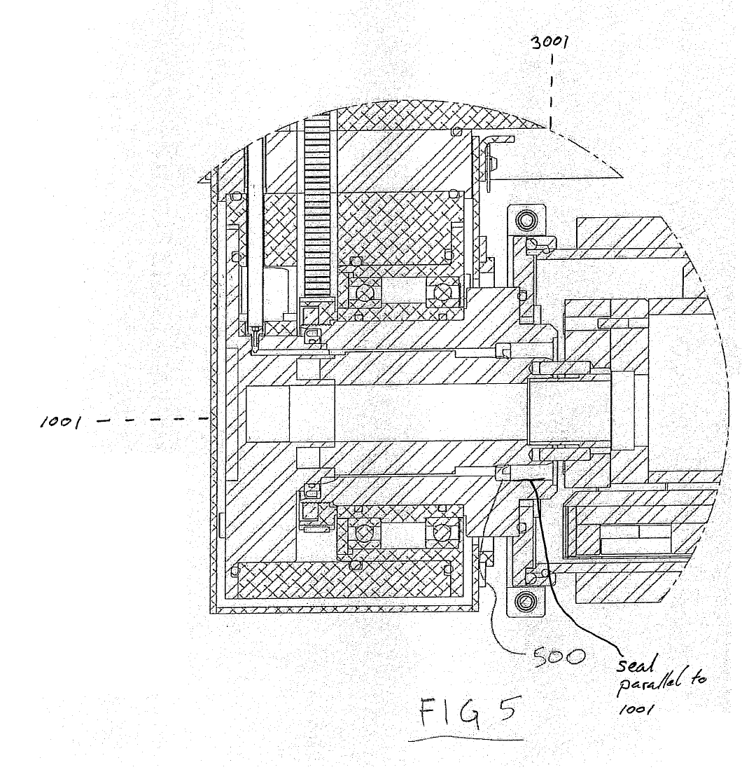

Various modifications can be made to the embodiment without departing from the scope of the invention. For example, the coolant seal is alternatively a lip seal 500 as shown in FIG. 5, where like numerals correspond to the meaning imparted thereto with respect to the aforementioned figures. The lip seal 500 is formed with a rotary seal surface parallel to axis 1001. Also, several types of rotary water seals are known and may also be utilized in other embodiments. Still further the vacuum seal can be a ferrofluid type or a lip seal type or some other type. By locating the rotary water seal inside the target shaft, more room is available on the outside of the target shaft for a durable, heavy-duty vacuum seal with oversized support bearings.

Electrical power can be delivered either though end block 102 or the opposite, supporting end block 103. In the embodiment shown, electrical power is commutated into the target tube 101 at the end of the target tube 101 supported by supporting end block 103. This avoids the problem of inductive heating in the vacuum seal assembly 401. When AC electrical current flows through the vacuum seal end block 102, inductive heating of the vacuum seal assembly 401 and other end block 102 components occurs. This is particularly a problem with Ferro fluid type couplings as the ferrofluid is readily heated by inductive coupling. In the case where AC current is commutated in the vacuum seal end block 102, the ferrofluid seal assembly 401 should be water cooled.

The invention has been described in terms of specific illustrative embodiments. It is intended that the invention not be limited by the embodiments shown and described. The variations of the invention described herein are not intended to be limiting to the scope of the invention. It will be appreciated by those skilled in the art that various other modifications may be made without departing from the scope of the invention. It is intended that the invention be limited in scope only by the claims appended hereto.

1. A rotary magnetron comprising:
an end block for rotatably supporting a target having a target shaft, said target defining an axis of rotation;
an elongate magnetic bar assembly disposed within said target;
a stator shaft affixed in said end block, one end of said stator shaft being coupled to said elongate magnetic bar assembly to support said elongate magnetic bar assembly, the target shaft extending over said stator shaft;
said target comprising a target shaft extending over said stator shaft and rotatable thereon around the axis of rotation; and
a rotating coolant seal disposed inside said target shaft and proximate to said one end of said stator shaft and proximate to said elongate magnetic bar assembly.

2. The rotary magnetron in accordance with claim 1, wherein said rotating coolant seal comprises:
a non-rotating first circumferential sealing surface carried on said stator shaft; and
a rotating second circumferential sealing surface carried on said target shaft and in sealing engagement with said first circumferential sealing surface.

3. The rotary magnetron in accordance with claim 2, wherein said first and said second circumferential sealing surfaces are disposed in a plane that is perpendicular to the axis of rotation.

4. The rotary magnetron in accordance with claim 2, wherein said first and said second circumferential sealing surfaces are disposed in a plane that is parallel to the axis of rotation.

5. The rotary magnetron in accordance with claim 3 or 4 further comprising a bearing assembly disposed in mechanical communication between said stator shaft and said target shaft to support said target shaft on said stator shaft, said target shaft being rotatably supported on said stator shaft, and said bearing assembly being spaced apart along the axis of rotation from the plane.

6. The rotary magnetron in accordance with claim 5, further comprising a vacuum seal assembly disposed between said stator shaft and said target shaft to provide a vacuum seal between said stator shaft and said target shaft, said vacuum seal assembly being spaced apart along the axis of rotation from the plane.

7. The rotary magnetron in accordance with claim 3 or 4, further comprising an integrated bearing and vacuum seal assembly disposed between said stator shaft and said target shaft to support said target shaft on said stator shaft and to provide a vacuum seal between said stator shaft and said target shaft, said target shaft being sealed and rotatably supported on said stator shaft, said integrated bearing and vacuum seal assembly being disposed in a first longitudinal position along the axis of rotation, and the plane is disposed at a second longitudinal position along the axis of rotation.

8. The rotary magnetron in accordance with claim 7, wherein said integrated bearing and vacuum seal assembly comprises ferromagnetic sealing fluid.

9. The rotary magnetron in accordance with one of claims 3 to 7, wherein at least one of said first and second sealing surfaces comprises a ceramic material.

10. The rotary magnetron in accordance with one of claims 3 to 7, wherein one of said first and second sealing surfaces is a ceramic material and the other of said first and second sealing surfaces is an inorganic carbon material.

11. The rotary magnetron in accordance with claim 1, wherein said stator shaft comprises a plurality of coolant fluid passages extending therein parallel to said axis and in fluid communication with said target.

12. The rotary magnetron in accordance with claim 10, wherein said stator shaft comprises a coolant fluid return passage extending along said axis and in fluid communication with said target.

13. The rotary magnetron of any of claims 1 to 11, wherein said stator shaft is independent of, and without a water bearing.

14. The rotary magnetron in accordance with any of claims 1 to 13, wherein said stator shaft further comprises coolant inlet passages that at said stator shaft have a summed inlet transverse cross-sectional area ratio to the stator area equal to or greater than 0.06:1.

15. The rotary magnetron in accordance with claim 14, wherein the ratio is between 0.06-0.12:1.

16. The rotary magnetron in accordance with any of claims 1 to 15, further comprising a distal end block in rotary contact with a distal end of said target tube.

17. A process for operating a rotary magnetron assembly comprising:
energizing the rotary magnetron of claim 1 under vacuum; and
flowing coolant therethrough in contact with a rotating coolant seal inside the target shaft proximate to one end of the stator shaft and proximate to the elongate magnetic bar assembly.

18. A process in accordance with claim 17, wherein said rotating coolant seal a non-rotating first circumferential sealing surface carried on said stator shaft, and a rotating second circumferential sealing surface carried on said target shaft and in sealing engagement with said first circumferential sealing surface.

19. A process in accordance with claim 18, further comprising disposing said first and said second circumferential sealing surfaces in a plane that is perpendicular or parallel to the axis of rotation.

20. A process in accordance with claim 19, further comprising providing a bearing assembly in mechanical communication disposed between said stator shaft and said target shaft to support said target shaft on said stator shaft, said target shaft bearing rotatably supported on said stator shaft, and said bearing assembly being spaced apart along the axis of rotation from the plane.

21. A process in accordance with claim 20, further comprising providing a vacuum seal assembly disposed between said stator shaft and said target shaft to provide a vacuum seal between said stator shaft and said target shaft, said vacuum seal assembly being spaced apart along the axis of rotation from said plane.

22. A process in accordance with claim 19, further comprising providing an integrated bearing and vacuum seal assembly disposed between said stator shaft and said target shaft to support said target shaft on said stator shaft and to provide a vacuum seal between said stator shaft and said target shaft, said target shaft being sealed and rotatably supported on said stator shaft, said integrated bearing and vacuum seal assembly being disposed in a first longitudinal position along the axis of rotation, and the plane is disposed at a second longitudinal position along the axis of rotation.

23. A process in accordance with claim 19, further comprising providing a ceramic material sealing surface for at least one of said first and second sealing surfaces and the other of said first and second sealing surfaces is an inorganic carbon material.

24. A process in accordance with any of claims 17 to 23, further comprising providing a stator shaft independent of and without a water bearing.

25. A process in accordance with any of claims 17 to 24, further comprising providing a plurality of coolant fluid inlet passages extending in said stator shaft parallel to the axis of rotation and in fluid communication with said target, said inlet passages at said stator shaft having a summed inlet transverse cross-sectional area ratio to a stator area equal to or greater than 0.06:1.

26. A process in accordance with claim 25, further comprising providing a coolant fluid return passage in said stator shaft extending along said axis and in fluid communication with said target.

27. A rotary magnetron comprising:
an end block for rotatably supporting a target having a target shaft, said target defining an axis of rotation;
an elongate magnetic bar assembly disposed within said target;
a stator shaft affixed in said end block, one end of said stator shaft being coupled to said elongate magnetic bar assembly to support said elongate magnetic bar assembly, the target shaft extending over said stator shaft;
said target comprising a target shaft extending over said stator shaft and rotatable thereon around the axis of rotation; and
coolant inlet passages extending in said stator shaft parallel to the axis of rotation and in fluid communication with said target, said inlet passages at said stator shaft having a summed inlet transverse cross-sectional area ratio to a stator area equal to or greater than 0.06:1.

28. The rotary magnetron in accordance with claim 27, wherein the ratio is between 0.06-0.12:1.

29. The rotary magnetron in accordance with claim 27 further comprising a central coolant fluid return passage in said stator shaft in fluid communication with said target.

30. The rotary magnetron of any of claims 27 to 29, wherein said stator shaft is independent of and without a water bearing.

31. The rotary magnetron in accordance with claims 27 to 30 further comprising any of a rotating coolant seal disposed inside said target shaft and proximate to said one end of said stator shaft and proximate to said elongate magnetic bar assembly.

32. The rotary magnetron in accordance with claim 31, wherein said rotating coolant seal has:
a non-rotating first circumferential sealing surface carried on said stator shaft; and
a rotating second circumferential sealing surface carried on said target shaft and in sealing engagement with said first circumferential sealing surface.

33. The rotary magnetron in accordance with claim 31, wherein said first and said second circumferential sealing surfaces are disposed in a plane that is perpendicular to the axis of rotation.

34. The rotary magnetron in accordance with claim 31, wherein said first and said second circumferential sealing surfaces are disposed in a plane that is parallel to the axis of rotation.

35. The rotary magnetron in accordance with claim 33 or 34, wherein at least one of said first and second sealing surfaces comprises a ceramic material.

36. The rotary magnetron in accordance with claim 33 or 34, wherein one of said first and second sealing surfaces is a ceramic material and the other of said first and second sealing surfaces is an inorganic carbon material.
